(19) United States
(12) Patent Application Publication
(10) Pub. No.: US 2021/0288159 A1
(43) Pub. Date: Sep. 16, 2021

(54) SEMICONDUCTOR DEVICE

(71) Applicants: Kabushiki Kaisha Toshiba, Tokyo (JP); Toshiba Electronic Devices & Storage Corporation, Tokyo (JP)

(72) Inventors: Toshiyuki Nishikawa, Nonoichi Ishikawa (JP); Hideto Sugawara, Nonoichi Ishikawa (JP)

(21) Appl. No.: 17/012,188

(22) Filed: Sep. 4, 2020

(30) Foreign Application Priority Data
Mar. 13, 2020 (JP) 2020-043857

(51) Int. Cl. H01L 29/45; H01L 23/532

(52) U.S. Cl. CPC H01L 29/452; H01L 23/53266; H01L 23/53252

(57) ABSTRACT

Provided is a semiconductor device including: a group III-V semiconductor layer containing n-type impurities; a first conductive layer provided on the group III-V semiconductor layer, the first conductive layer containing titanium (Ti) and a first element that can be a p-type impurity of the group III-V semiconductor layer, the first conductive layer having a first region and a second region, a first element concentration of the second region being higher than that of the first region; and a second conductive layer provided on the first conductive layer.

### CROSS-REFERENCE TO RELATED APPLICATION

This application is based upon and claims the benefit of priority from Japanese Patent Application No. 2020-043857, filed on Mar. 13, 2020, the entire contents of which are incorporated herein by reference.

### FIELD

Embodiments described herein relate generally to semiconductor devices.

### BACKGROUND

In some cases, an electrode for taking a current may be formed on a semiconductor layer of a semiconductor device. It is preferable that the contact between the semiconductor layer and the electrode is ohmic.

### BRIEF DESCRIPTION OF THE DRAWINGS

FIG. 1 is a schematic cross-sectional diagram of a semiconductor device according to an embodiment;

FIG. 2 is a schematic cross-sectional diagram illustrating processes of manufacturing a semiconductor device according to Comparative Embodiment;

FIG. 3 is a schematic cross-sectional diagram illustrating a semiconductor device according to Comparative Embodiment;

FIG. 4 is an example of a SIMS profile of the semiconductor device according to Comparative Embodiment;

FIG. 5 is another example of the SIMS profile of the semiconductor device according to Comparative Embodiment;

FIG. 6 is another example of the SIMS profile of the semiconductor device according to Comparative Embodiment; and

FIG. 7 is an example of a SIMS profile the semiconductor device according to the embodiment.

### DETAILED DESCRIPTION

Hereinafter, an embodiment will be described with reference to the drawings. In addition, in the following description, the same members and the like will be denoted by the same reference numerals, and the description of the members and the like once described will be appropriately omitted.

In this specification, in order to illustrate the positional relationship of parts and the like, the upward direction of the drawings is referred to as “upper”, and the downward direction of the drawings is referred to as “lower”. In this specification, the terms “upper” and “lower” do not necessarily indicate the relationship with the direction of gravity.

### Embodiment

A semiconductor device according to an embodiment includes: a group III-V semiconductor layer containing n-type impurities; a first conductive layer provided on the group III-V semiconductor layer, the first conductive layer containing titanium (Ti) and a first element that can be a p-type impurity of the group III-V semiconductor layer, the first conductive layer having a first region and a second region, a first element concentration of the second region being higher than that of the first region; and a second conductive layer provided on the first conductive layer.

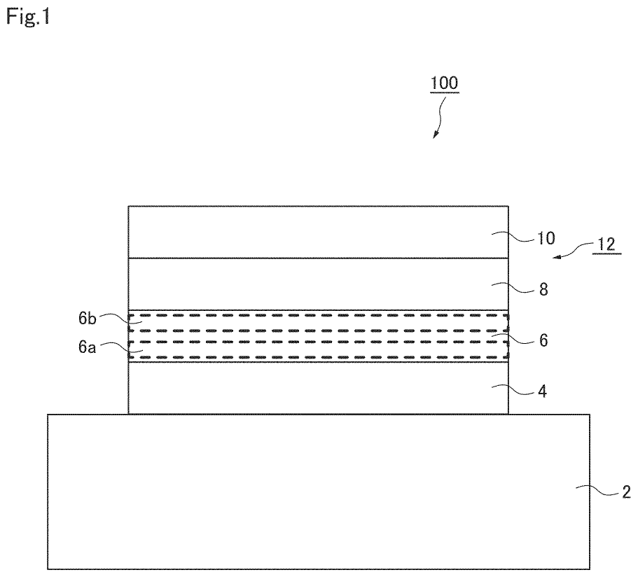

FIG. 1 is a schematic cross-sectional diagram of a semiconductor device 100 according to this embodiment.

The semiconductor device 100 includes a group III-V semiconductor layer 2, a fifth conductive layer 4, a first conductive layer 6, and a second conductive layer 12.

The fifth conductive layer 4, the first conductive layer 6, and the second conductive layer 12 are used, for example, as electrodes of the group III-V semiconductor layer 2.

The group III-V semiconductor layer 2 contains an n-type impurity. Herein, the group III-V semiconductor is a semiconductor using a group III element and a group V element. The group III-V element is, for example, aluminum (Al), gallium (Ga), or indium (In). The group V element is, for example, nitrogen (N), phosphorus (P), arsenic (As) or antimony (Sb) The n-type impurity is, for example, silicon (Si), tin (Sn), sulfur (S), selenium (Se), or tellurium (Te).

The fifth conductive layer 4 is provided on the group III-V semiconductor layer 2. The fifth conductive layer 4 is used for ohmic contact with the group III-V semiconductor layer 2. The fifth conductive layer 4 contains, for example, 99.5 at % of gold (Au) and 0.5 at % of germanium (Ge).

The first conductive layer 6 is provided on the fifth conductive layer 4. The first conductive layer 6 contains titanium (Ti) and a first element that can be a p-type impurity of the group III-V semiconductor layer 2. Herein, the first element is zinc (Zn), magnesium (Mg), or beryllium (Be).

The first conductive layer 6 has a first region 6a and a second region 6b. The first element concentration of the second region 6b is higher than the first element concentration of the first region 6a. For example, the second region 6b is provided on the first region 6a. However, the second region 6b may be provided below the first region 6a. In addition, in FIG. 1, the shapes of the first region 6a and the second region 6b in the cross section of the semiconductor device 100 are illustrated as rectangles. However, the shapes of the first region 6a and the second region 6b in the cross section of the semiconductor device 100 are not limited to rectangles.

The second conductive layer 12 is provided on the first. conductive layer 6. The second conductive layer 12 includes a third conductive layer 8 and a fourth conductive layer 10. The third conductive layer 8 is, for example, a Pt conductive layer containing platinum (Pt). The fourth conductive layer 10 is, for example, an Au conductive layer containing Au. For example, a bonding wire (not illustrated) is bonded onto the fourth conductive layer 10. It is preferable that the Au used for the fourth conductive layer 10 contains as few impurities as possible in order to secure good bonding properties. The third conductive layer 8 is used in order to improve the adhesion property between the first conductive layer 6 and the fourth conductive layer 10.

Next, a method of manufacturing the semiconductor device 100 according to this embodiment will be described.

First, the fifth conductive layer 4 containing 99.5 at % of Au and 0.5 at % of Ge is formed on the group III-V semiconductor layer 2 which is, for example, a gallium arsenide (GaAs) layer containing n-type impurities. The film thickness of the fifth conductive layer 4 is, for example, 100 nm.

Next, the first conductive layer 6 containing Ti and Zn as the first element is formed on the fifth conductive layer 4. In addition, in the formation of the first conductive layer 6, for example, Ti and Zn are simultaneously formed in the first conductive layer 6 by so-called co-sputtering. However, the Ti film and the Zn film may be alternately formed by sputtering. The film thickness of the first conductive layer 6 is, for example, 100 nm.

Next, the third conductive layer 8 which is, for example, a Pt conductive layer is formed on the first conductive layer 6. The film thickness of the third conductive layer 8 is, for example, 70 nm.

Next, the fourth conductive layer 10 which is, for example, an Au conductive layer is formed on the third conductive layer 8. The film thickness of the fourth conductive layer 10 is, for example, 600 nm.

The fifth conductive layer 4, the first conductive layer 6, the third conductive layer 8 and the fourth conductive layer 10 are formed by, for example, sputtering or a vacuum evaporation method.

Next, heat treatment is performed, for example, in an argon (Ar) atmosphere for 3 minutes at 370° C. Accordingly, the first region 6a and the second region 6b are formed in the first conductive layer 6. In this manner, the semiconductor device 100 according to this embodiment is obtained.

Next, the functions and effects of the semiconductor device 100 according to this embodiment will be described.

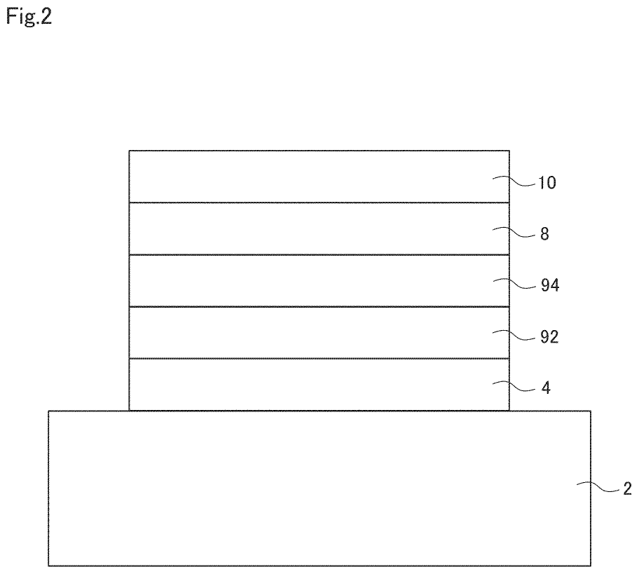

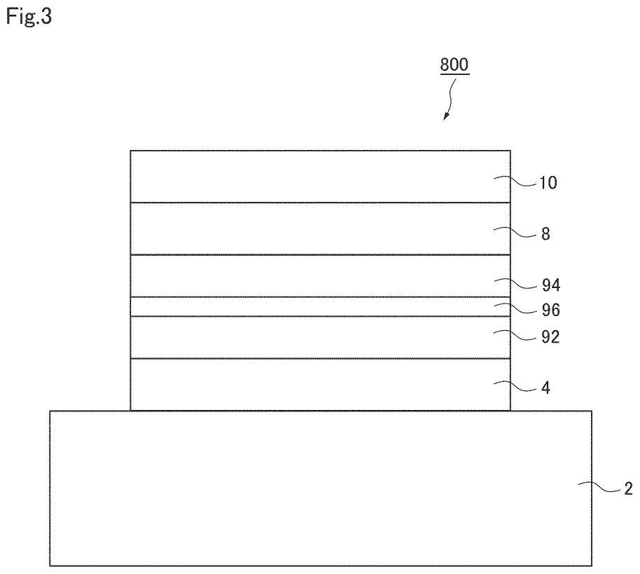

FIG. 2 is a schematic cross-sectional diagram illustrating processes of manufacturing a semiconductor device 800 according to Comparative Embodiment. FIG. 3 is a schematic cross-sectional diagram illustrating the semiconductor device 800 according to Comparative Embodiment. A method of manufacturing the semiconductor device 800 will be described. As illustrated in FIG. 2, the fifth conductive layer 4 containing, for example, 99.5 at % of Au and 0.5 at % of Ge is formed on the group III-V semiconductor layer 2 which is, for example, a GaAs layer containing n-type impurities. A conductive layer 92 containing, for example, Au and Zn is formed on the fifth conductive layer 4. A conductive layer 94 containing, for example, Ti is formed on the conductive layer 92. The third conductive layer 8 which is, for example, a Pt conductive layer is formed on the conductive layer 94. The fourth conductive layer 10 which is, for example, an Au conductive layer is formed on the third conductive layer 8. After that, by performing heat treatment, ohmic characteristics as an electrode is secured, and as illustrated in FIG. 3, a conductive layer 96 where a portion of Zn in the conductive layer 92 and Ti in the conductive layer 94 is alloyed is formed between the conductive layer 92 and the conductive layer 94. The conductive layer 96 functions as a barrier metal that prevents diffusion of constituent elements and other elements in the group III-V semiconductor layer 2.

Herein, there has been a problem in that the form of the alloy of Zn and Ti becomes unstable and the function as a barrier metal is degraded due to process variations in the heat history applied in the heat treatment and the subsequent chip manufacturing processes. That is, when AuZn and Ti are formed in a stacked structure and subjected to heat treatment, Zn forms an alloy with Ti and diffuses also in the direction (direction of the group III-V semiconductor layer 2) opposite to the conductive layer 94 containing Ti. For this reason, the change of the concentration of the Zn to be alloyed with Ti occurs along with the change of the heat treatment process, and the alloy form becomes unstable. As a result, there has been a problem in that a variation also occurs in the barrier function.

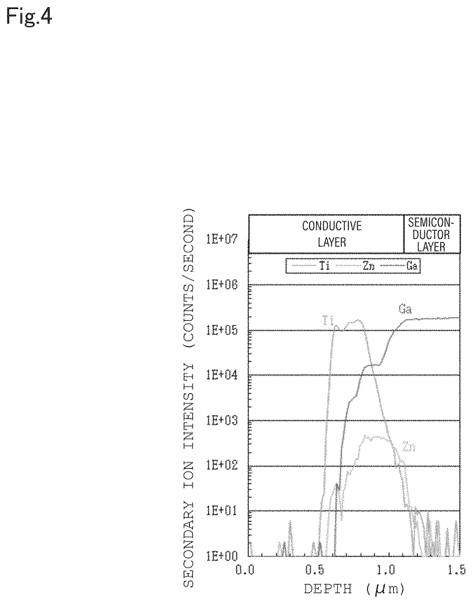

FIG. 4 is an example of a secondary ion mass spectroscopy (SIMS) profile of the semiconductor device 800 according to Comparative Embodiment. FIG. 4 is a SIMS profile when the barrier property of the conductive layer 96 is maintained. In FIG. 4, the “semiconductor layer” is the group III-V semiconductor layer 2. The “conductive layer” includes a conductive layer provided on the group III-V semiconductor layer 2. For example, in the case of FIG. 4, the “conductive laver” includes the fifth conductive layer 4, the conductive layer 92, the conductive layer 96, the conductive layer 94, the third conductive layer 8, and the fourth conductive layer 10.

In FIG. 4, it can be understood that Ga which is a constituent element of the group III-V semiconductor layer 2 is diffused in the stacked metal (conductive layer), but it can be understood that the diffusion of Ga is stopped in the portion in which Ti and Zn is alloyed and high secondary ion intensities of Ti and Zn are observed.

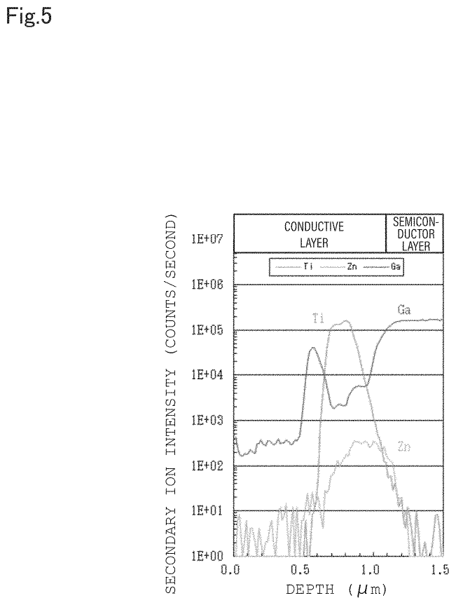

FIG. 5 illustrates another example of the secondary ion mass spectroscopy (SIMS) profile of the semiconductor device 800 according to Comparative Embodiment. FIG. 5 is a SIMS profile when the barrier property of the conductive layer 96 is lowered. Although the TiZn profile is not so different as compared with the SIMS profile of FIG. 4, it can be understood that the spread of the Zn profile is slightly increased, and Ga penetrates to the surface of the stacked metal (to the surface of the fourth conductive layer 10). The fourth conductive layer 10 functions as a bonding layer to which a bonding wire (not illustrated) or the like is connected, but Ga reaching the surface forms an oxide film on the outermost surface of the fourth conductive layer 10 and can be a factor that hinders the bonding property. As described above, even in the conductive layer 96 formed through the same forming process, there is a problem in stability of performance due to process variations in heat history applied in the heat treatment and the subsequent chip manufacturing processes.

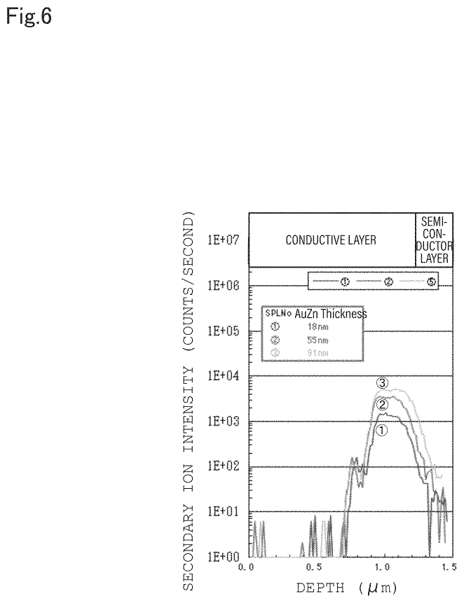

FIG. 6 is another example of the SIMS of the semiconductor device 800 according to Comparative Embodiment. FIG. 6 illustrates an attempt to increase the amount of Zn in the metal by increasing the deposited film thickness at the time of forming the conductive layer 92 in order to stabilize the form of the Ti—Zn alloy. As a result, although the Zn amount itself is increased as illustrated in FIG. 6, it has not been possible to prevent the influence of diffusion to the semiconductor side due to the heat treatment. For this reason, there has been a problem in that the form of the Ti—Zn alloy cannot be stabilized.

Therefore, in the semiconductor device 100 according to this embodiment, the first conductive layer 6 containing titanium (Ti) and the first element that can be the p-type impurity of the group III-V semiconductor layer is formed. That is, in Comparative Embodiment, AuZn and Ti are sequentially formed in a stacked structure and are subjected to heat treatment to form an alloy of Zn and Ti. On the contrary, in the semiconductor device 100 according to this embodiment, the structure previously formed in the form of Ti—Zn is subjected to the heat treatment to form the TiZn alloy.

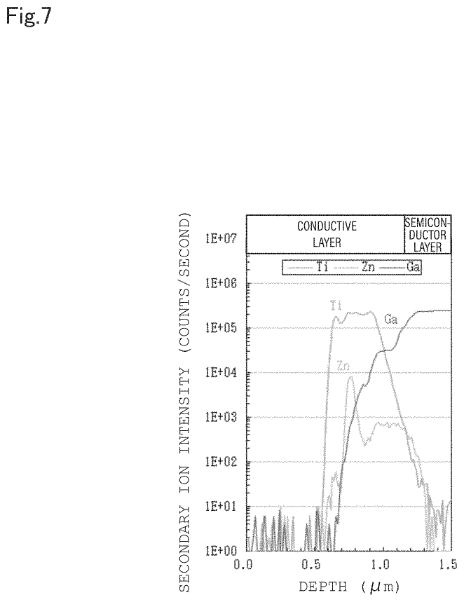

FIG. 7 is an example of a SIMS profile of the semiconductor device 100 according to the embodiment. A region where the secondary ion intensity of Zn is particularly high between the depth of about 0.7 μm and the depth of about 0.8 μm is the second region 6b. In addition, a region where the secondary on intensity of Zn is lower than that of the second region 6b between the depth of about 0.8 μm and the depth of about 1.2 μm is the first region 6a. In both the first region 6a and the second region 6b, the secondary ion intensity of Zn is increased as compared with that in the SIMS profiles illustrated in FIGS. 4 and 5.

In FIG. 7, the diffusion of Ga is suppressed in a portion deeper than the depth portion corresponding to the second region 6b. For this reason, it can be understood that the first conductive layer 6 functions as a good barrier layer. In addition, in the SIMS profile of FIG. 4 in which Ga diffusion is stopped in Comparative Embodiment, the Ga diffusion front profile and the Zn profile are lowered in the same region. On the contrary, in the SIMS profile of FIG. 7, a decrease in the Ga amount is observed in a portion deeper than the region where the Zn amount is large. Specifically, in the SIMS profile of FIG. 4, the secondary ion intensity of Ga is 1×10⁴ or more at a depth where the secondary ion intensity of Zn is high and the secondary ion intensity of Ti is high. On the contrary, in the SIMS profile of FIG. 7, the secondary ion intensity of Ga is 1×10³ or less at a depth where the secondary ion intensity of Zn is high and the secondary ion intensity of Ti is high. As described above, it is considered that, in the semiconductor device 100 according to the embodiment, since the amount of Zn is large, the amount of alloy with Ti is also large, sufficient barrier performance is obtained, and as a result, the margin for stopping Ga diffusion is increased.

The difference between the SIMS profiles of the semiconductor device 100 according to this embodiment and the semiconductor device 800 according to Comparative Embodiment is due to the above-described formation of the first conductive layer 6 containing Ti and the first element that can be a p-type impurity of the group III-V semiconductor layer. In addition, in the semiconductor device 100, since the secondary ion intensity of Zn is high, the diffusion Ga is suppressed. Furthermore, since the second region 6b having the first element concentration higher than that of the first region 6a is provided, it is considered that the element diffusion is further suppressed particularly in the second region 6b.

In addition, the film thickness of each of the fifth conductive layer 4 and the first conductive layer 6 is preferably in the range of 50 to 500 nm. In addition, the heat treatment temperature is preferably in the range of 280° C. to 400° C.

According to the embodiment, the impurities diffused from the semiconductor layer can be effectively suppressed to the conductive layer. For this reason, for example, in the bonding layer to which a metal wire or the like is connected as the surface layer, it is possible to suppress a factor that an oxide film is formed due to the impurity diffusion and hinders the bonding property.

In addition, in the SIMS profiles illustrated in FIGS. 4, 5, 6, and 7, absolute calibration of the concentration of each element is not performed. For this reason, the height relationship of concentration between the elements illustrated in FIGS. 4, 5, and 6 is different from that of the actual semiconductor device 800. In addition, the height relationship between the elements illustrated in FIG. 7 is different from that of the actual semiconductor device 100. However, in the SIMS profiles illustrated in FIGS. 4, 5, 6, and 7, it is possible to compare the amounts of Zn, Ti, and Ga between the SIMS profiles illustrated in different drawings.

In addition, in the SIMS profile illustrated in FIG. 4, the comparison of the Ti amount in the depth direction, the comparison of the Zn amount in the depth direction, and the comparison of the Ga amount in the depth direction can be respectively performed. In addition, in the SIMS profile illustrated in FIG. 4, the comparison of the Ti amount and the Zn amount, the comparison of the Ti amount and the Ga amount, and the comparison of the Zn amount, and the Ga amount cannot be performed, as described above, because the absolute calibration of the concentration of each element has not been performed. The same applies to the SIMS profiles illustrated in FIGS. 5, 6, and 7.

According to the semiconductor device according to this embodiment, it is possible to provide a semiconductor device having electrodes with low contact resistance.

While certain embodiments have been described, these embodiments have been presented by way of example only, and are not intended to limit the scope of the inventions. Indeed, semiconductor devices described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

What is claimed is:

1. A semiconductor device comprising:
a group III-V semiconductor layer containing n-type impurities;
a first. conductive layer provided on the group III-V semiconductor layer, the first conductive layer containing titanium (Ti) and a first element that can be a p-type impurity of the group III-V semiconductor layer, the first conductive layer having a first region and a second region, a first element concentration of the second region being higher than. that of the first region; and.
a second conductive layer provided on the first conductive layer.

2. The semiconductor device according to claim 1, wherein the second region is provided on the first region.

3. The semiconductor device according to claim 1, wherein the first element is zinc (Zn), magnesium. (Mg), or beryllium. (Be).

4. The semiconductor device according to claim 1, wherein the second conductive layer includes a third conductive layer containing platinum (Pt) and a fourth conductive layer being provided on the third conductive layer and containing gold (Au).

5. The semiconductor device according to claim 1, further comprising a fifth conductive layer provided between the group III-V semiconductor layer and the first conductive layer.

6. The semiconductor device according to claim 5, wherein the fifth conductive layer contains gold (Au) and germanium (Ge).

7. The semiconductor device according to claim 6, wherein the fifth conductive layer contains 99.5 at % of gold (Au) and 0.5 at % of germanium (Ge).
